(19) United States
(12) Patent Application Publication
(10) Pub. No.: US 2018/0180674 A1
(43) Pub. Date: Jun. 28, 2018

(54) EMBEDDED FIRMWARE CONTENT TRACING

(71) Applicant: Microsoft Technology Licensing, LLC, Redmond, WA (US)

(72) Inventor: Garrett D. BLANKENBURG, Sammamish, WA (US)

(21) Appl. No.: 15/721,368

(22) Filed: Sep. 29, 2017

Related U.S. Application Data
(60) Provisional application No. 62/438,724, filed on Dec. 23, 2016.

(51) Int. Cl. G01R 31/317; G01R 31/3177

(52) U.S. Cl. CPC G01R 31/31705; G01R 31/31723; G01R 31/3177

(57) ABSTRACT

A debug system includes a hardware debug module configured to load a trace function and a plurality of memory addresses of a target chip to the target chip using a hardware debug input port of the target chip. The trace function may be hooked to a specified function of the target chip. A firmware function of the target chip calls the specified function of the target chip to cause the trace function to execute. Upon execution, the trace function reads content of the plurality of memory addresses of the target chip and outputs the content to an output port of the target chip.

### CROSS-REFERENCE TO RELATED APPLICATIONS

The present application claims benefit of priority to U.S. Provisional Patent Application No. 62/438,724, entitled “Embedded Firmware Content Tracing” and filed on Dec. 23, 2016, which is specifically incorporated by reference for all that it discloses and teaches.

### BACKGROUND

Electronic systems such as a computer, a set-top box, a game console, a phone, etc., include several integrated circuits (“ICs,” also referred to as a chips). Such IC chips include a microprocessor, a graphics processor, a memory chip, a storage controller, a digital signal processor, etc. One or more settings of such chips may be provided by hardware registers and fuses. The chips may come with default settings that are intended to allow software to start executing on the chip. Furthermore, such chips also include one or more ports that may be used for debugging the chip.

### SUMMARY

The hardware debug system disclosed herein includes a hardware debug module configured to load a trace function and a plurality of memory addresses of a target chip to the target chip using a hardware debug input port of the target chip. The trace function may be hooked to a specified function of the target chip. A firmware function of the target chip calls the specified function of the target chip to cause the trace function to execute. Upon execution, the trace function reads content of the plurality of memory addresses of the target chip and outputs the content to an output port of the target chip.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

Other implementations are also described and recited herein.

### BRIEF DESCRIPTIONS OF THE DRAWINGS

A further understanding of the nature and advantages of the present technology may be realized by reference to the figures, which are described in the remaining portion of the specification. In the figures, like reference numerals are used throughout several figures to refer to similar components.

FIG. 1 illustrates an example system disclosing the hardware debug host working with a debug target.

FIG. 2 illustrates an alternative example system disclosing the hardware debug host working with a debug target.

FIG. 3 illustrates example flow of information for the hardware debug host working with a debug target.

FIG. 4 illustrates example operations of a hardware debug system disclosed herein.

FIG. 5 illustrates an example system that may be useful in implementing the hardware debug system disclosed herein.

### DETAILED DESCRIPTIONS

The described technology includes a hardware debug module that works with a hardware debug application to allow a user to trace content from a target chip. Specifically, the hardware debug module disclosed herein uses hardware debug port of the target chip to load a trace function in volatile memory of the target chip. The hardware debug module also loads a plurality of memory addresses of the target chip to the volatile memory of the target chip. The target chip may be an integrated circuit (IC) such as a microprocessor, a graphic processor, a digital signal processor, etc.

The trace function loaded by the hardware debug module may be a compiled trace function. Such trace function may be hooked to a specified function of the target chip such that the trace function executes before or after the specified function of the target chip is called. In one implementation, the hardware debug module hooks the specified function on the target chip with the dynamically loaded trace function such that when the specified function is executed by the target chip, the content of the plurality of memory addresses of the target chip is output to an input/output (I/O) port of the target chip before and/or after the specified function gets executed. A debugger application running on a host computer, such as a personal computer (PC) may monitor the I/O port of the target chip to read the content of the plurality of memory addresses of the target chip and display the content via a user interface. This allows a user debugging firmware of a target chip to review the content of the target chip over the user interface of the debugger application.

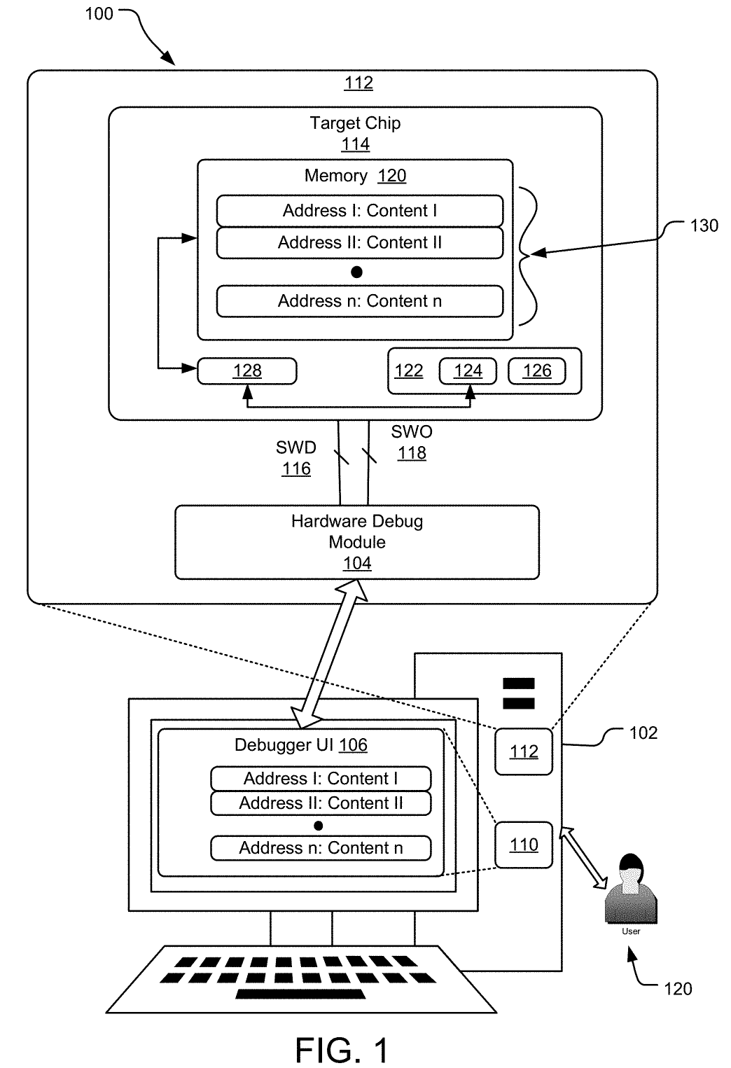

FIG. 1 illustrates an example debugging system 100 disclosing a hardware debug host 102 working with a hardware debug module 104. The hardware debug host 102 may be a computing device, such as a PC, a laptop, a server, etc. The hardware debug host 102 may include a debugger application 110 that communicates with the hardware debug module 104. The hardware debug module 104 may be configured on a circuit board 112 in the hardware debug host 102. In an alternative implementation, the hardware debug module 104 may be configured on the circuit board 112 that is external to the hardware debug host 102.

The hardware debug host 102 also includes a debugger application 110 that works with the hardware debug module 104 to present data using a debugger user interface (UI) 106. A user 120 may use the debugger UI 106 to interact with the hardware debug module 104 and to view output from the hardware debug module 104. The hardware debug module 104 is configured to communicate with a target chip 114 using a hardware debug port 116 of the target chip 114. The hardware debug port 116 may be, for example, a serial wire debug (SWD) bus port, a Joint Test Action Group (JTAG) bus (IEEE 1149.1) port, a microchip in-circuit serial programming (ICSP) bus port, etc.

In one implementation, the hardware debug module 104 loads a trace function 124 to a volatile memory 122, such as a random-access memory (RAM), of the target chip 114 via the hardware debug port 116. Furthermore, the hardware debug module 104 also loads various memory addresses 126 of the target chip 114 to the volatile memory 122 via the hardware debug port 116. Furthermore, the hardware debug module 104 may also specify the size of content at each of the memory addresses 126 of the target chip 114 together with the memory addresses 126.

The trace function 124 loaded on the volatile memory 122 may be hooked to a specified firmware function 128 of the target chip 114. Such hooking the trace function 124 to the specified firmware function 128 results in execution of the trace function 124 before or after execution of the specified firmware function 128 when the specified firmware function 128 is called. For example, the trace function 124 may be a compiled function that acts as pre-hook code that executes before the execution of the specified firmware function 128. Alternatively, the trace function 124 may be a compiled function that acts as post-hook code the executes after the execution of the specified firmware function 128. The trace function 124 may be hooked to the specified firmware function 128 in a number of different manners. For example, the trace function 124 may be hooked to a specific function that is called after the variable that is of interest gets updated. Alternatively, the trace function 124 may be hooked to a function that is called at a desired frequency in view of the desired sample rate. Yet alternatively, a timer generating the periodic SYSTICK interrupts may be configured to generate SYSTIK inputs at a desired sample rate. In such an implementation, the trace function 124 may be hooked to the interrupt service routine (ISR) executed in response to the SYSTICK interrupt.

The trace function 124 reads through the dynamically loaded memory addresses 126 and transmits the content at these addresses back to the hardware debug module 104. Specifically, the trace function 124 may be configured to read the content of the memory addresses 126 from a memory 120 of the target chip 114. For example, the memory 120 may be the firmware memory of the target chip 114. The content 130 from the memory addresses 126 may be read and output to an I/O port 118 of the target chip 114. For example, such an I/O port 118 may be serial wire output (SWO) trace port, a universal asynchronous receiver/transmitter port, a universal serial bus (USB port, etc.). Alternatively, the content 130 from the memory addresses 126 may be stored in a flash memory on the hardware debug module 104.

The debugger application 110 monitors the I/O port 118 and displays the content 130 from the memory addresses 126 to the user 120 via the debugger UI 106. Alternatively, the debugger application 110 reads the content 130 from the memory addresses 126 from the flash memory on the hardware debug module 104 and displays the read content via the debugger UI 106.

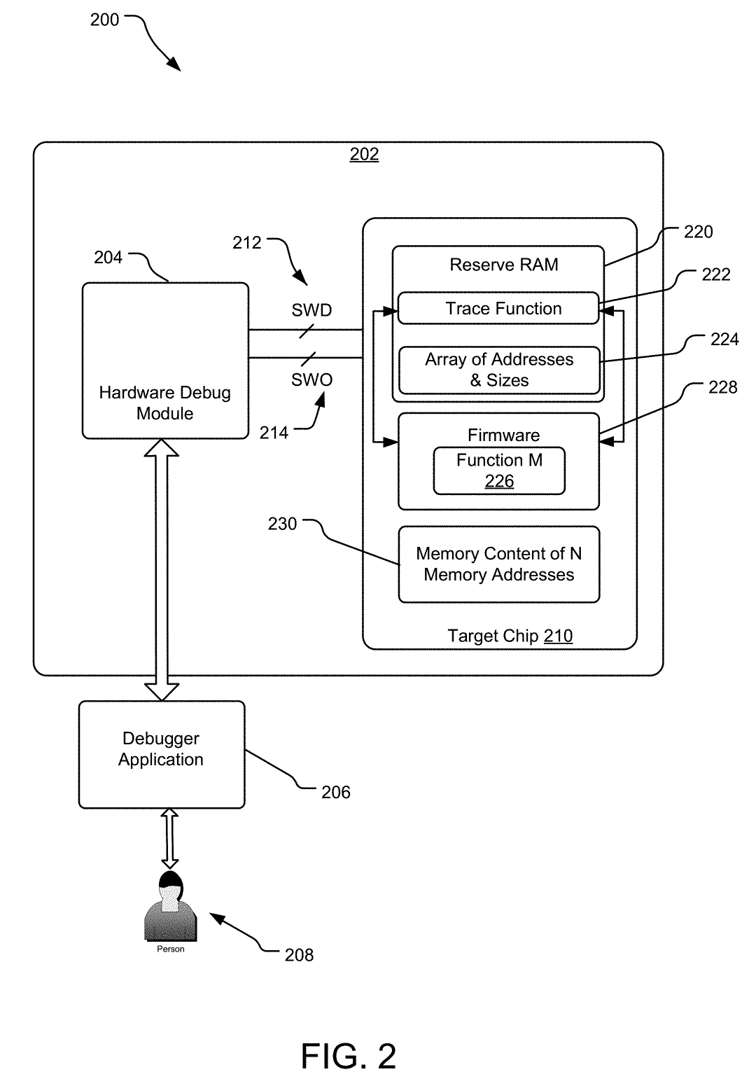

FIG. 2 illustrates an alternative example system 200 disclosing a debugger application 206 using a hardware debug system 202. Specifically, the hardware debug system 202 includes a hardware debug module 204 that communicates with a target chip 210 using a hardware debug connection 212. Such hardware debug connection 212 may be, for example, a serial wire debug (SWD) bus port, a Joint Test Action Group (JTAG) bus (IEEE 1149.1) port, a microchip in-circuit serial programming (ICSP) bus port, etc. The hardware debug module 204 may be configured to communicate with a debugger application 206 using a USB or other communication mode.

In one implementation, the debugger application 206 may be a resident on a computing device such as a desktop, a laptop, a server, etc. A user 208 may access the debugger application 206 to give instructions to the hardware debug module 204 and/or review output from the hardware debug module 204 as presented by a GUI of the debugger application 206.

The target chip 210 may be a microprocessor, a digital signal processor, a graphics processor, etc., that have volatile memory, non-volatile memory, one or more registers, one or more central processing units (CPUs), etc. In one example implementation, the target chip 210 includes reserve RAM 220 that may be used to store temporary information. The hardware debug module 204 may use the hardware debug connection 212 to load a trace function 222 and an array of memory addresses and sizes for each of the addresses (referred to as an “address array” 224) into the reserve RAM 220. The address array 224 may include a plurality of memory addresses of a memory 230 of the target chip 210.

In one implementation, the trace function 222 may be a compiled function. The trace function 222 may be hooked to a specific function of the target chip firmware 228, such as a function M 226. Specifically, the trace function 222 may be hooked to the function M 226 such that when the function M 226 is called, the trace function 222 is executed either before an execution of the function M 226 or after the execution of the function M 226. The trace function 222 may include various operations to read the content of the address array 224. Specifically, for each address of the address array 224, the trace function 222 reads memory content 230 as specified by the size of each of such specified address array 224.

Furthermore, the trace function 222 outputs the read content to an I/O port 214 of the target chip 210. For example, such an I/O port 214 may be a serial wire output (SWO) trace port, a universal asynchronous receiver/transmitter port, a universal serial bus (USB port, etc. The debugger application 206 may monitor the I/O port 214 and display the read data to the user 208 via a GUI of the debugger application 206. Alternatively, the memory content 230 for the address array 224 may be stored in a flash memory on the hardware debug module 204. In such an implementation, the debugger application 206 may read the read data from the flash memory and display it to the user 208 via a GUI of the debugger application 206.

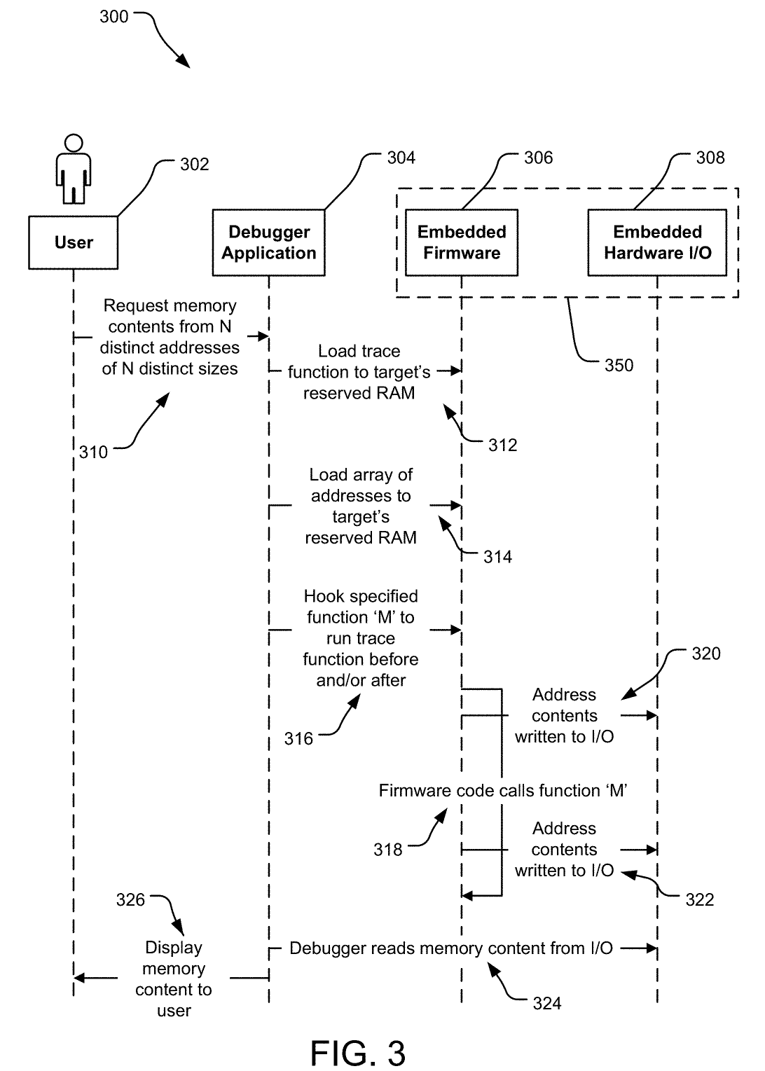

FIG. 3 illustrates example flow of information 300 for a hardware debug system working with a target chip. Specifically, the hardware debug system may include a debugger application 304 that uses embedded firmware 306 of a target chip 350 and outputs read content from the target chip 350 to an embedded hardware I/O 308 of the target chip 350. The debugger application 304 may be resident on a computing device, such as a personal computer and may be used by a user 302 to read memory content from the target chip 350.

At 310, the user requests memory content from N distinct addresses of N distinct sizes from the debugger application 304. At 312, the debugger application 304 loads a trace function to the target chip 350's reserve RAM. The trace function may be a compiled trace function. At 314, the debugger application 304 also loads an array of the N distinct addresses specifying the N distinct sizes to the target chip 350's reserve RAM. Once the trace function and the array of addresses is loaded to the target chip 350's reserve RAM, at 316, the trace function is hooked to a specific function (referred to as “M function”) of the firmware of the target chip 350, such that the trace function is run before and/or after the specific function is executed.

At 318, firmware of the target chip 350 calls the M function. As the trace function is hooked to the M function, upon the execution of the M function, the trace function is executed either before or after the execution of the M function. If the trace function is executed before the M function, at 320, the content for the array of addresses is written to an I/O port of the target chip 350. If the trace function is executed after the M function, at 322, the content for the array of addresses is written to an I/O port of the target chip 350. At 324, the debugger application 304, which monitors the I/O port of the target chip 350, reads the memory content from the I/O port of the target chip 350 and at 326 the memory content is displayed to the user 302.

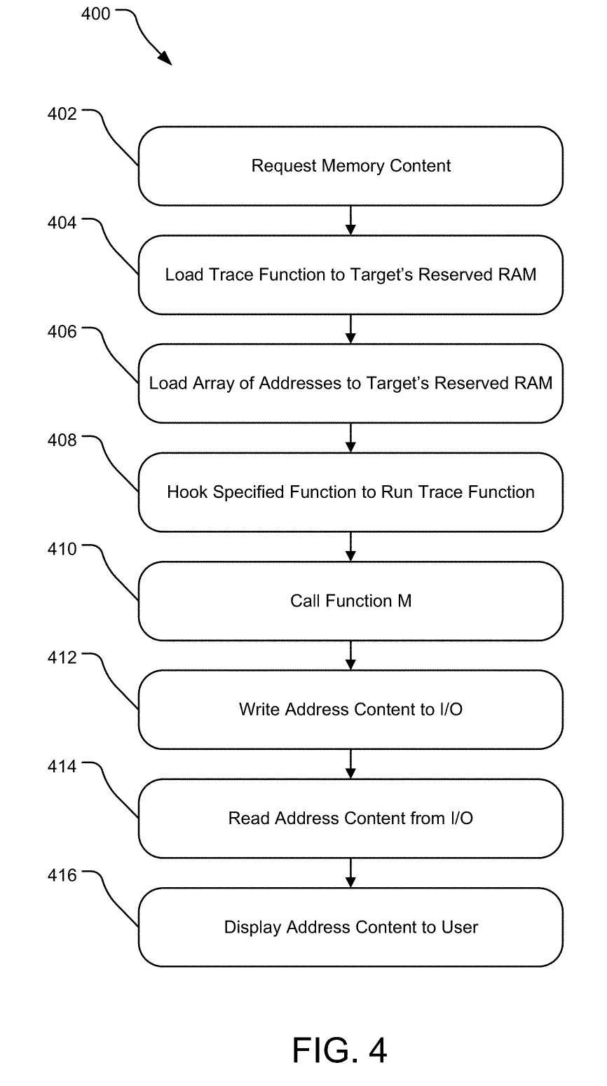

FIG. 4 illustrates example operations 400 of a hardware debug system disclosed herein. Specifically, an operation 402 requests content from memory of a target chip. For example, a debugger application may send such request to a hardware debug module. An operation 404 loads a trace function to a target chip's reserve RAM. Such trace function may be a compiled trace function configured to read memory content for specific addresses and to output the read content to an I/O port of the target chip. An operation 406 loads an array of addresses to the reserve RAM of the target chip. Furthermore, the operation 406 may also load size of content to be read at each of the addresses in the array of addresses. In one implementation, the array of addresses may be specified by a user via a debugger application running on a computing device. The array of addresses may include addresses for firmware memory of the target chip.

An operation 408 hooks the trace function to a specific function (referred to as “function M”) of the target chip firmware to run the trace function. In one implementation, the operation 408 hooks the trace function to a specific firmware function that exists in the firmware image or to a normal call stack of the specific firmware function.

Subsequently, the firmware of the target chip calls the function M at operation 410. As the trace function is hooked to the function M, the trace function is executed before or after the execution of the function M. As result of the execution of the trace function, an operation 412 writes content for the addresses in the array of addresses to an I/O port of the target chip. An operation 414 reads the address content from the I/O port and an operation 416 displays the address content to a user. The operations 400 allow a user to view content of specified memory addresses of a target chip firmware using a GUI of a computing device.

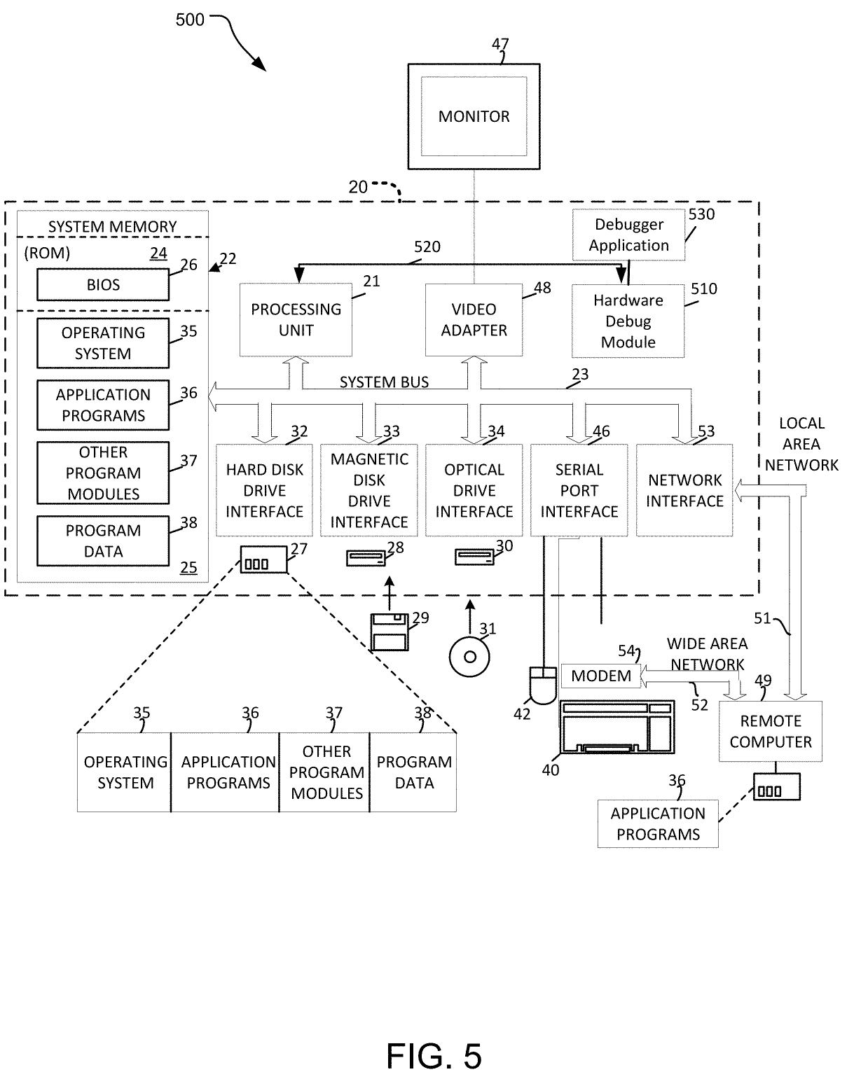

FIG. 5 illustrates an example system 500 that may be useful in implementing the hardware debug system disclosed herein. The example hardware and operating environment of FIG. 5 for implementing the described technology includes a computing device, such as a general-purpose computing device in the form of a computer 20, a mobile telephone, a personal data assistant (PDA), a tablet, smart watch, gaming remote, or other type of computing device. In the implementation of FIG. 5, for example, the computer 20 includes a processing unit 21, a system memory 22, and a system bus 23 that operatively couples various system components including the system memory to the processing unit 21. There may be only one or there may be more than one processing unit 21, such that the processor of a computer 20 comprises a single central-processing unit (CPU), or a plurality of processing units, commonly referred to as a parallel processing environment. The computer 20 may be a conventional computer, a distributed computer, or any other type of computer; the implementations are not so limited.

In the example implementation of the computing system 500, the computer 20 also includes a hardware debugging module 510 such as a hardware debug host disclosed herein. The hardware debugging module 510 may communicate with a processing unit 21 via a hardware debug bus 520 such as a JTAG bus, an SWD bus, etc. In such an implementation, the hardware debugging module 510 may be able to read content of the processing unit 21 as per instructions from a debugger application 530.

The system bus 23 may be any of several types of bus structures including a memory bus or memory controller, a peripheral bus, a switched fabric, point-to-point connections, and a local bus using any of a variety of bus architectures. The system memory 22 may also be referred to as simply the memory, and includes read-only memory (ROM) 24 and random-access memory (RAM) 25. A basic input/output system (BIOS) 26, containing the basic routines that help to transfer information between elements within the computer 20, such as during start-up, is stored in ROM 24. The computer 20 further includes a hard disk drive 27 for reading from and writing to a hard disk, not shown, a magnetic disk drive 28 for reading from or writing to a removable magnetic disk 29, and an optical disk drive 30 for reading from or writing to a removable optical disk 31 such as a CD ROM, DVD, or other optical media.

The computer 20 may be used to implement a hardware debug module configured as illustrated in FIG. 1. In one implementation, one or more instructions of the hardware debug module may be implemented in memory of the computer 20, such as the read-only memory (ROM) 24 and random-access memory (RAM) 25, etc.

Furthermore, instructions stored on the memory of the computer 20 may be used to generate a trace function using one or more operations disclosed in FIG. 4. Similarly, instructions stored on the memory of the computer 20 may also be used to implement one or more operations of FIG. 4.

The hard disk drive 27, magnetic disk drive 28, and optical disk drive 30 are connected to the system bus 23 by a hard disk drive interface 32, a magnetic disk drive interface 33, and an optical disk drive interface 34, respectively. The drives and their associated tangible computer-readable media provide nonvolatile storage of computer-readable instructions, data structures, program modules and other data for the computer 20. It should be appreciated by those skilled in the art that any type of tangible computer-readable media may be used in the example operating environment.

A number of program modules may be stored on the hard disk drive 27, magnetic disk 29, optical disk 31, ROM 24, or RAM 25, including an operating system 35, one or more application programs 36, other program modules 37, and program data 38. A user may generate reminders on the personal computer 20 through input devices such as a keyboard 40 and pointing device 42. Other input devices (not shown) may include a microphone (e.g., for voice input), a camera (e.g., for a natural user interface (NUI)), a joystick, a game pad, a satellite dish, a scanner, or the like. These and other input devices are often connected to the processing unit 21 through a serial port interface 46 that is coupled to the system bus 23, but may be connected by other interfaces, such as a parallel port, game port, or a universal serial bus (USB). A monitor 47 or other type of display device is also connected to the system bus 23 via an interface, such as a video adapter 48. In addition to the monitor 47, computers typically include other peripheral output devices (not shown), such as speakers and printers.

The computer 20 may operate in a networked environment using logical connections to one or more remote computers, such as remote computer 49. These logical connections are achieved by a communication device coupled to or a part of the computer 20; the implementations are not limited to a particular type of communications device. The remote computer 49 may be another computer, a server, a router, a network PC, a client, a peer device or other common network node, and typically includes many or all of the elements described above relative to the computer 20. The logical connections depicted in FIG. 5 include a local-area network (LAN) 51 and a wide-area network (WAN) 52. Such networking environments are commonplace in office networks, enterprise-wide computer networks, intranets and the Internet, which are all types of networks.

When used in a LAN-networking environment, the computer 20 is connected to the local area network 51 through a network interface or adapter 53, which is one type of communications device. When used in a WAN-networking environment, the computer 20 typically includes a modem 54, a network adapter, a type of communications device, or any other type of communications device for establishing communications over the wide area network 52. The modem 54, which may be internal or external, is connected to the system bus 23 via the serial port interface 46. In a networked environment, program engines depicted relative to the personal computer 20, or portions thereof, may be stored in the remote memory storage device. It is appreciated that the network connections shown are example and other means of communications devices for establishing a communications link between the computers may be used.

In an example implementation, software or firmware instructions for requesting, processing, and rendering mapping data may be stored in system memory 22 and/or storage devices 29 or 31 and processed by the processing unit 21. Mapping data and/or layer prioritization scheme data may be stored in system memory 22 and/or storage devices 29 or 31 as persistent data-stores.

In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include wired media such as a wired network or direct-wired connection, and wireless media such as acoustic, RF, infrared and other wireless media.

Some embodiments of the hardware debug system may comprise an article of manufacture. An article of manufacture may comprise a tangible storage medium to store logic. Examples of a storage medium may include one or more types of computer-readable storage media capable of storing electronic data, including volatile memory or non-volatile memory, removable or non-removable memory, erasable or non-erasable memory, writeable or re-writeable memory, and so forth. Examples of the logic may include various software elements, such as software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. In one embodiment, for example, an article of manufacture may store executable computer program instructions that, when executed by a computer, cause the computer to perform methods and/or operations in accordance with the described embodiments. The executable computer program instructions may include any suitable type of code, such as source code, compiled code, interpreted code, executable code, static code, dynamic code, and the like. The executable computer program instructions may be implemented according to a predefined computer language, manner or syntax, for instructing a computer to perform a certain function. The instructions may be implemented using any suitable high-level, low-level, object-oriented, visual, compiled and/or interpreted programming language.

The hardware debug system disclosed herein may include a variety of tangible computer-readable storage media and intangible computer-readable communication signals. Tangible computer-readable storage can be embodied by any available media that can be accessed by the hardware debug system disclosed herein and includes both volatile and nonvolatile storage media, removable and non-removable storage media. Tangible computer-readable storage media excludes intangible and transitory communications signals and includes volatile and nonvolatile, removable and non-removable storage media implemented in any method or technology for storage of information such as computer readable instructions, data structures, program modules or other data. Tangible computer-readable storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other tangible medium which can be used to store the desired information and which can be accessed by the hardware debug system disclosed herein. In contrast to tangible computer-readable storage media, intangible computer-readable communication signals may embody computer readable instructions, data structures, program modules or other data resident in a modulated data signal, such as a carrier wave or other signal transport mechanism. The term “modulated data signal” means a signal that has one or more of its characteristics set or changed in such a manner as to encode information in the signal. By way of example, and not limitation, intangible communication signals include signals moving through wired media such as a wired network or direct-wired connection, and signals moving through wireless media such as acoustic, RF, infrared and other wireless media.

The implementations described herein are implemented as logical steps in one or more computer systems. The logical operations may be implemented (1) as a sequence of processor-implemented steps executing in one or more computer systems and (2) as interconnected machine or circuit modules within one or more computer systems. The implementation is a matter of choice, dependent on the performance requirements of the computer system being utilized. Accordingly, the logical operations making up the implementations described herein are referred to variously as operations, steps, objects, or modules. Furthermore, it should be understood that logical operations may be performed in any order, unless explicitly claimed otherwise or a specific order is inherently necessitated by the claim language. The above specification, examples, and data, together with the attached appendices, provide a complete description of the structure and use of exemplary implementations.

What is claimed is:

1. A system comprising:
a hardware debug module configured to load a trace function and a plurality of memory addresses of a target chip to the target chip using a hardware debug input port of the target chip, wherein the trace function is hooked to a specified function of the target chip;
a firmware function stored on the target chip that is configured to call the specified function of the target chip to cause the trace function to execute, wherein the trace function reads content of the plurality of memory addresses of the target chip and outputs the content to an output port of the target chip; and
a debugger application configured to monitor the output port of the target chip to read the content of the plurality of memory addresses and to display the content to a user.

2. The system of claim 1, wherein the hardware debug module is further configured to load size of each of the plurality of memory addresses of the target chip.

3. The system of claim 2, wherein the trace function is further configured to read the content of each of the plurality of memory addresses of the target chip for the size of each of the plurality of memory addresses of the target chip.

4. The system of claim 1, wherein the trace function is loaded to a volatile memory of the target chip.

5. The system of claim 1, wherein the hardware debug input port is a serial wire debug (SWD) port.

6. The system of claim 1, wherein the output port of the target chip is a serial wire output (SWO) port.

7. The system of claim 1, wherein the hardware debug input port is a Joint Test Action Group (JTAG) bus input port and the hardware debug output port is a Joint Test Action Group (JTAG) bus output port.

8. The system of claim 1, wherein the trace function is further configured to output the content to a flash file.

9. The system of claim 8, wherein the debugger application is configured to read the content from the flash file using a universal service bus (USB) port.

10. The system of claim 1, wherein the plurality of memory addresses of the target chip are addresses of memory mapped input output (MMIO) peripherals of the target chip.

11. The system of claim 10, wherein the specified function of the target chip is an interrupt service routine of a timer peripheral of the target chip.

12. An apparatus, comprising:
a hardware debug module configured to load a trace function and a plurality of memory addresses of a target chip to the target chip using a hardware debug input port of the target chip, wherein the trace function is hooked to a specified function of the target chip and is configured to read content of the plurality of memory addresses of the target chip and output the content to an output port of the target chip upon execution of the specified target function.

13. The apparatus of claim 12, wherein the hardware debug module is configured to load the trace function into a volatile memory of the target chip.

14. The apparatus of claim 12, wherein the hardware debug input port is a serial wire debug (SWD) port.

15. The apparatus of claim 12, wherein the output port of the target chip is a serial wire output (SWO) port.

16. The apparatus of claim 12, wherein the specified function of the target chip is an interrupt service routine of a timer peripheral of the target chip.

17. A method, comprising:
loading a trace function to a volatile memory of a target chip using a hardware debug input port of the target chip;
loading an array of addresses to the volatile memory of the target chip using a hardware debug input port of the target chip;
hooking the loaded trace function to a specified function of the target chip; and
calling the specified function of the target chip.

18. The method of claim 17, further comprising executing the trace function upon execution of the specified function to generate output from the array of addresses to an output port of the target chip.

19. The method of claim 18, wherein the specified function of the target chip is an interrupt service routine of a timer peripheral of the target chip.

20. The method of claim 17, wherein the plurality of memory addresses of the target chip are addresses of memory mapped input output (MMIO) peripherals of the target chip.
